(19) United States
(12) Patent Application Publication
(10) Pub. No.: US 2018/0272371 A1
(43) Pub. Date: Sep. 27, 2018

(54) NOZZLE AND LIQUID SUPPLY DEVICE

(71) Applicant: Kabushiki Kaisha Toshiba, Minato-ku (JP)

(72) Inventors: Takahiro TERADA, Yokohama (JP); Masayuki TANAKA, Yokohama (JP); Shiguma KATO, Yokohama (JP); Kaori DEURA, Yokohama (JP); Morihiro MACHIDA, Chuo (JP)

(73) Assignee: Kabushiki Kaisha Toshiba, Minato-ku (JP)

(21) Appl. No.: 15/556,189

(22) PCT Filed: Sep. 8, 2015
(86) PCT No.: PCT/JP2015/075511

§ 371 Date: Sep. 6, 2017

(30) Foreign Application Priority Data
Mar. 18, 2015 (JP) 2015-054830

(51) Int. Cl. B05C 5/00; B05C 11/10; H01L 21/67

(52) U.S. Cl. CPC B05C 5/004; H01L 21/6715; B05C 11/10

(57) ABSTRACT

A nozzle includes a body. The body includes a supply port to which a liquid is supplied, a vent from which the liquid is discharged downward, and a flow channel that extends between the supply port and the vent. The flow channel includes: a storage including a first part through which the liquid flows downward to the vent, and a second part provided downstream of the first part, through which the liquid flows upward to the vent; and an exhaust capable of exhausting a gas upstream of the second part while the liquid is not discharged from the vent and is stored in the storage. The storage includes a third part connecting the first part and the second part. The exhaust includes a bypass channel that leads to parts upstream and downstream of the third part in the flow channel.

### FIELD

Embodiments of the present invention relate to a nozzle and a liquid supply device.

### BACKGROUND

Conventionally, there have been known liquid supply devices that discharge, through a nozzle, a chemical liquid onto a workpiece such as a wafer from above.

### CITATION LIST

Patent Literature 1: Japanese Laid-open Patent Publication No. 8-281184 A

Patent Literature 2: Japanese Laid-open Patent Publication No. 2005-44836 A

Patent Literature 3: Japanese Laid-open Patent Publication No. 10-119775 A

### SUMMARY OF THE INVENTION

### Problem to be Solved by the Invention

The above liquid supply devices may drip the chemical liquid, from the nozzle onto the workpiece after the discharge, which results in deteriorating the quality of the workpiece. It is thus useful to attain a nozzle having a novel structure which is prevented from dripping.

### Means for Solving Problem

A nozzle of an embodiment comprises a body. The foody is provided with a supply port to which a liquid is supplied, a vent from which the liquid is discharged downward, and hi flow channel that, extends between the supply port and the vent. The flow channel includes: a storage including a first part through which the liquid flows downward to the vent, and a second part provided downstream of the first part through which the liquid flows upward to the vent; and an exhaust capable of exhausting a gas upstream of the second part while the liquid is not discharged from the vent and is stored in the storage.

### BRIEF DESCRIPTION OF DRAWINGS

FIG. 1 is a schematic view of a chemical liquid coating device according to a first embodiment.

FIG. 2 is a cross-sectional view of a nozzle according to the first embodiment.

FIG. 3 is a cross-sectional, view of a part of a pipe according to the first embodiment.

FIG. 4 is a cross-sectional view of a nozzle according to a second embodiment.

FIG. 5 is a cross-sectional view of the nozzle according to the second embodiment, when a liquid is stored in an exhaust.

FIG. 6 is a cross-sectional view of a nozzle according to a third embodiment.

FIG. 7 is a cross-sectional view of the nozzle according to the third embodiment, when a liquid is stored in an exhaust.

FIG. 8 is a cross-sectional view of a nozzle according to a fourth embodiment.

FIG. 9 is a cross-sectional view of a nozzle according to a fifth embodiment.

FIG. 10 is a cross-sectional view of FIG. 9 taken along the line X-X.

FIG. 11 is a cross-sectional view of a nozzle according to a sixth embodiment.

FIG. 12 is a cross-sectional view of a nozzle according to a seventh embodiment.

FIG. 13 is a cross-sectional view of a nozzle according to an eighth embodiment.

FIG. 14 is a cross-sectional view of a nozzle according to a ninth embodiment.

FIG. 15 is a cross-sectional view of a nozzle according to a tenth embodiment.

FIG. 16 is a cross-sectional view of a nozzle according to an eleventh embodiment.

### DETAILED DESCRIPTION

Hereinafter, embodiments will be described with reference to the accompanying drawings. The following exemplary embodiments include components having same or similar functions. The components having same or similar functions are denoted by the same reference numerals, and a redundant description thereof may be omitted.

### First Embodiment

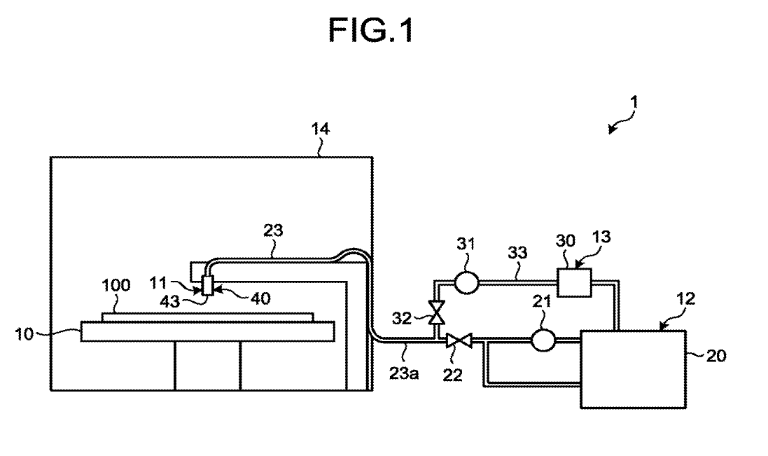

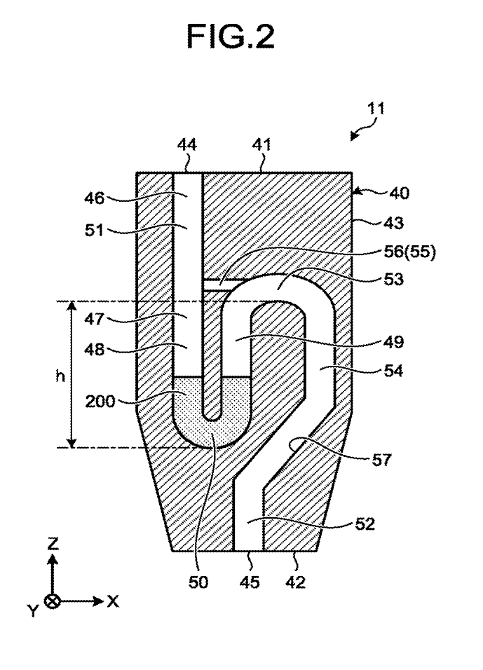

A first embodiment will be described with reference to FIGS. 1 to 3. A chemical liquid coating device 1 illustrated in FIG. 1 applies a chemical liquid 200 (FIG. 2) such as resist liquid onto a substrate 100 such as a wafer. The chemical liquid coating device 1 is an example of a liquid supply device, the substrate 100 is an example of an object (workplace), and the chemical liquid 200 is an example of liquid.

As illustrated in FIG. 1, the chemical liquid coating device 1 includes a support unit 10, a nozzle 11, a supplier 12, a collector 13, and a cover 14.

The support unit 10 detachably supports the substrate 100. The support unit 10 rotates the substrate 100 thereon by a driving source such as a motor. The support unit 10 is disposed in the cover 14.

The nozzle 11 is disposed above the substrate 100 on the support unit 10 with a space from the substrate 100. The nozzle 11 is supplied with the chemical liquid 200 from the supplier 12 and ejects it to the substrate 100 from above.

The supplier 12 includes a tank 20, a pump 21, a valve 22, and a pipe 23. The tank 20 stores the chemical liquid 200. The tank 20 is connected to the nozzle 11 via the pipe 23. The pump 21 and the valve 22 are provided in the middle of the pipe 23, that is, between the tank 20 and the nozzle 11. The pump 21 can supply the chemical liquid 200 from the tank 20 to the nozzle 11. The chemical, liquid 200 is supplied to the nozzle 11 through the pipe 23. The valve 22 is provided between the pump 21 and the nozzle 11 to be able to open and close a flow channel in the pipe 23.

The collector 13 includes a tank 30, a pump 31, a valve 32, and a pipe 33. The pipe 33 is connected to a point between the nozzle 11 and the valve 22 in the pipe 23 and to the tank 20. The tank 30, the pump 31, and the valve 32 are provided in the middle of the pipe 33. The tank 30, the pump 31, and the valve 32 are disposed in order from the tank 20 side in the pipe 33. The pump 31 suctions and generates a suction force to the nozzle 11 side. Thereby, the pump 31 suctions the chemical liquid 200 from the nozzle 11 and the pipe 23. The chemical liquid 200 suctioned by the pump 31 is stored in the tank 30. The valve 32 can open and close the flow channel in the pipe 33.

To apply the chemical liquid 200 onto the substrate 100, the chemical liquid coating device 1 opens the valve 22 and closes the valve 32. Then, with the substrate 100 in rotation on the support unit 10, the pump 21 supplies the chemical liquid 200 from the tank 20 to the nozzle 11. The supplied chemical liquid 200 is discharged from the nozzle 11 onto the substrate 100. The discharged chemical liquid 200 spreads over the entire surface of the substrate 100 by a centrifugal force.

Upon completion of the application of the chemical liquid 200, the chemical liquid coating device 1 performs a suck back. In the suck back process, the chemical liquid coating device 1 closes the valve 22 and opens the valve 32. Then, the pump 31 performs a suction. As a result, the chemical liquid 200 is suctioned from the nozzle 11 and a part 23a of the pipe 23 between the nozzle 11 and the valve 22. The suctioned chemical liquid 200 is discharged from the pump 31 to the tank 30 for storage. After suctioning the chemical liquid 200 in this manner, the chemical liquid coating device 1 closes the valve 32. Through the suck back process as above, the nozzle 11 is inhibited from dripping.

Next, the nozzle 11 will be described in detail. In the following, art X direction, a Y direction, and a Z direction are defined for convenience of description. The X direction, the Y direction, and the Z direction are orthogonal to one another. The Z direction is along the top to bottom (vertical direction) of a body 40 of the nozzle 11.

As illustrated in FIG. 2, the nozzle 11 includes the body 40. The body 40 has an elongate shape and is made of a highly chemical-resistant material such as a ceramic material, a fluorine-based resin, or a vinyl chloride-based resin. The longitudinal direction (axial direction) of the body 40 is along the vertical direction (Z direction) of the body 40. The lateral direction (width direction) of the body 40 is along the X direction and the Y direction. The body 40 has a substantially columnar exterior. The body 40 has a top face 41, a bottom face 42, and a side face 43 as outer faces (surfaces). The top face 41 is at one longitudinal end (top end) of the body 40 and may also foe referred to as an end face. The top face 41 has a circular planar shape. The bottom face 42 is at the other longitudinal end (bottom end) of the body 40 and may also be referred to as an end face. The bottom face 42 has a circular planar shape. The bottom face 42 is directed to the support unit 10 and the substrate 100. The side face 43 is at a lateral end of the body 40 and may also be referred, to as a peripheral face. The side face 43 extends between the top face 41 and the bottom face 42. The side face 43 has a cylindrical shape.

In addition, the body 40 is provided with a supply port 44, a vent 45, and a flow channel 46. The supply port 44 is provided in. the top face 41. The pipe 23 is connected to the supply port 44. The chemical liquid 200 is supplied, to the supply port 44 from the supplier 12. The vent 45 is provided in the bottom face 42. The vent 45 is connected to the vent 45 via the flow channel 46. The vent 45 ejects downward the chemical liquid 200, which has been supplied to the supply port 44 and flowed through the flow channel 46.

The flow channel 46 extends between the supply port 44 and the vent 45. In the flow channel 46, a supply port 44 side is an upstream side and a vent 45 side is a downstream side. The supplied chemical liquid 200 flows from the supply port 44 to the vent 45 in the flow channel 46.

The flow channel 46 includes a storage 47. The storage 47 can store the chemical liquid 200. The storage 47 has a substantial U-shape. The depth of the storage 47 is denoted by a dimension h in FIG. 2. The storage 47 includes a first part 48, a second part 49, and a third part 50. The first part 48 extends vertically in the body 40. In the first part 48, the chemical liquid 200 flows downward to the vent 45. The second part 49 is downstream of tine first part 48. The second part 49 extends vertically in the body 40. In the second part 49, the chemical liquid 200 flows upward to the vent 45. The third part 50 extends between the downstream end of the first part 48 and the upstream end of the second part 49 to connect the first part 48 and the second part 49. The third part 50 has an upward bent shape (curved shape). The second part 49 is an example of a first part, and the first part 48 is an example of a second part. The storage 47 may also be referred to as a liquid storage or a chamber. The first part 48 may also be referred to as a downstream part or a downstream channel. The second part 49 may also be referred to as an upstream part or an upstream channel.

The third part 50 may also foe referred to as a bent or a bent.

An upstream end of the first part 48 is connected to the supply port 44 via a flow channel 51. The flow channel 51 extends vertically in the body 40. A downstream end of the second part 49 is connected to the vent 45 via a flow channel 52. The flow channel 52 is on the downstream side of the second part 49 and leads to the vent 45. The flow channel 52 includes a connection 53 and an extension 54. The connection 53 is connected to the downstream end of the second part 49. The connection 53 has a downward bent shape (curved shape). The extending 54 extends downward from a downstream end of the connection 53 to the vent 45. The extension 54 may also be referred to as a downstream part or a downstream channel.

The body 40 further includes an exhaust 55. The exhaust 55 includes a bypass channel 56. The bypass channel 56 leads to the flow channel 51 and the flow channel 52. The flow channel 51 is upstream of the third part 50 in the flow channel 46. The flow channel 52 is downstream of the third part 50 in the flow channel 46. Specifically, the bypass channel 56 leads to the connection 53 of the flow channel 52. That, is, the bypass channel 56 connects the flow channel 51 and the connection 53. The bypass channel 56 is connected to upstream of the first part 48 and a point above the second part 49 in the flow channel 46. The diameter of the bypass channel 56 is smaller than the diameter of the flow channel 46 as an example. The diameter of the bypass channel 56 may be equal, to or larger than the diameter of the flow channel 46. While the chemical liquid 200 is not discharged from the vent 45 and is stored in the storage 47 (illustrated in FIG. 2), the bypass channel 56 can work to exhaust a gas from the upstream side to the downstream side of the second part 49 of the storage 47. The flow channel 51 is an example of the part upstream from the third part 50 in the flow channel 46, and the flow channel 52 is an example of the part downstream from the third part 50 in the flow channel 46.

In the present embodiment, the arithmetic average roughness of a surface 57 of the flow channel 46 in the body 40 is set to larger than 10 μm. The body 40 having the above configuration can be manufactured by an additive manufacturing apparatus such as a 3D printer.

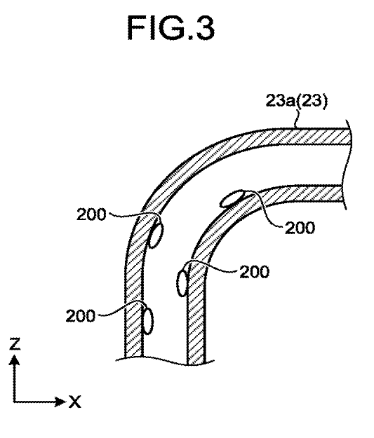

With the nozzle 11 having the above configuration, the chemical liquid 200 supplied from the supplier 12 to the supply port 44 is discharged downward from the vent 45 through the flow channel 46. Through the such back process, the chemical liquid 200 in the flow channel 46 is returned from the supply port 44 to the tank 30. However, the chemical liquid 200 may remain in a droplet state in the pipe 23 or the nozzle 11, for example, as illustrated in FIG. 3, even after the suck back process. In this case, the droplets of the chemical liquid 200 remaining on the upstream side of the storage 47 move downward by gravity and is stored in the storage 47 (FIG. 2). This can inhibit the nozzle 11 from dripping.

FIG. 2 illustrates the state of the flow channel 46 when blocked by the chemical liquid 200 stored in the storage 47. A gas dissolved in the stored chemical liquid 200 in the storage 47 rises and moves to the upstream side and flows to the downstream side of the storage 47 through the bypass channel 56. This inhibits an increase in the pressure upstream of the storage 47.

As described above, in the present embodiment, while the chemical liquid 200 is not discharged from the vent 45 and is stored in the storage 47, the exhaust 55 can exhaust the gas occurring upstream of the second part 49. This can suppress an increase in the pressure of the gas upstream of the storage 47 and inhibits the gas from extruding the chemical liquid 200 from the storage 47. Thus, the nozzle 11 is prevented from dripping.

In the present embodiment, the storage 47 includes the third part 50 connecting the first part 48 and the second part 49, and the exhaust 55 includes the bypass channel 56 leading to the upstream flow channel 51 and the downstream flow channel 52 of the third part 50 in the flow channel 46. Thereby, the exhaust 55 can exhaust the gas from upstream to downstream of the second part 49 through the bypass channel 56.

Furthermore, in the present embodiment, the bypass channel 56 is connected to the point above the second part 49 in the flow channel 46. Thus, even having flowed through the bypass channel 56 from the flow channel 51, the chemical liquid 200 flows to the second part 49, and is accumulated in the storage 47. This prevents the nozzle 11 from dripping.

Furthermore, in the present embodiment, the arithmetic average roughness of the surface 57 of the flow channel 46 in the body 40 is set to larger than 10 μm. Due to a relatively large unevenness on the surface 57, a contact area between the remaining chemical liquid 200 57 and the surface 57 can be increased. This makes it difficult for the remaining chemical liquid 200 to move on the surface 57, which prevents the nozzle 11 from dripping.

### Other Embodiments

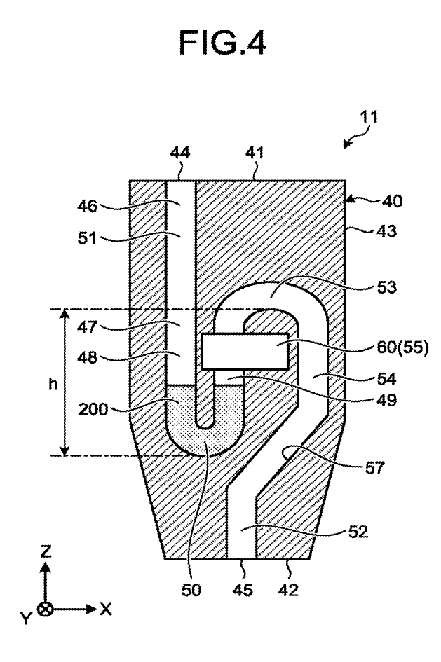

Next, nozzles 11 of other embodiments (second to eleventh embodiments) will be described with reference to FIGS. 4 to 16. The nozzles 11 of the other embodiments partially have similar configurations to that of the nozzle 11 of the first embodiment. Thus, the other embodiments can attain same or similar effects as those of the first embodiment based on configurations similar to that of the first embodiment. Hereinafter, differences between the nozzles 11 of the other embodiments and the nozzle 11 of the first embodiment will be mainly described.

### Second Embodiment

As illustrated in FIG. 4, the nozzle 11 of the present embodiment includes a flow channel 46 having a fourth part 60. The fourth part 60 is included In a second part 49. The fourth part 60 has a larger cross section orthogonal to an extending direction of the flow channel 46 than the rest of the storage 47. The fourth part 60 has a rectangular or cylindrical shape. The fourth part 60 is included in an exhaust 55. In the present embodiment, the exhaust 55 does not include the bypass channel 56. Both the fourth part 60 and the bypass channel 56 may be included in the exhaust 55. The fourth part 60 may also be referred to as a large cross-section part or a storage.

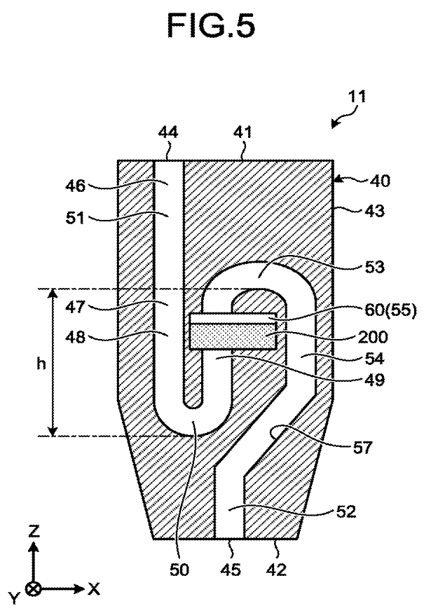

In the above-configured nozzle 11, while tine chemical liquid 200 in the storage 47 blocks the flow channel 46 (in FIG. 4), at gas dissolved in the chemical liquid 200 rises and moves to upstream of the storage 47, increasing a pressure upstream of the storage 47. The gas upstream then extrudes the chemical liquid 200 to downstream of the storage 47. FIG. 5 illustrates the state of the fourth part 60 that it includes an area containing a gas but no chemical liquid 200 at the top as a result of the stored chemical liquid 200 in the storage 47 extruded to downstream by the gas upstream at a predetermined pressure or higher and moved into the fourth part 60. In this state, a surface tension of the top of the chemical liquid 200 stored in the fourth part 60 is smaller than that of the chemical liquid 200 (FIG. 4) stored in the storage 47 other than the fourth part 60. Thus, because of the smaller surface tension of the top of the chemical liquid 200 stored in the fourth part 60, a gas downstream of the fourth part 60 can flow through the fourth part 60 to downstream of the fourth part 60. That is, while the chemical liquid 200 is not discharged from a vent 45 and is stored in the storage 47, the fourth part 60 can exhaust a gas from upstream to downstream of the second part 49 of the storage 47.

As described above, in the present embodiment, the fourth part 60 has a larger cross section orthogonal to the extending direction of the flow channel 46 than the rest of the storage 47. This makes it possible for the exhaust 55 to exhaust the gas from the upstream side to the downstream side of the second part 49 of the storage 47 through the fourth part 60.

### Third Embodiment

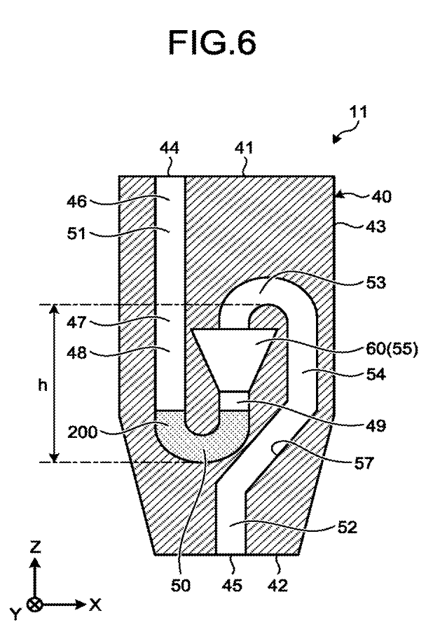

As illustrated in FIG. 6, the nozzle 11 of the present embodiment includes a fourth part 60 in a flow channel 46. However, the fourth part 60 of the present embodiment is different from the fourth part 60 of the second embodiment in the shape having a cross section, orthogonal to the extending direction of the flow channel 46, which increases in size upward.

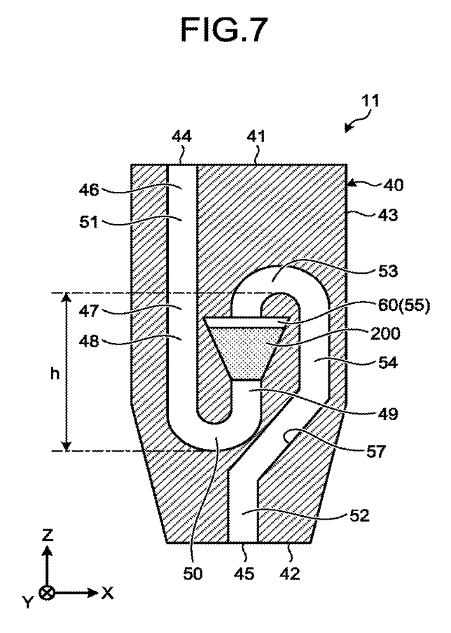

FIG. 7 illustrates the state of the fourth part 60 that it includes an area containing the gas but no chemical liquid 200 at the top as a result of the stored chemical liquid 200 in the storage 47 extruded to downstream by a gas upstream at a predetermined pressure or higher and moved into the fourth part 60. In this state, as in the second embodiment, a surface tension of the top of the chemical liquid 200 stored in the fourth part 60 is smaller than that of the chemical liquid 200 (FIG. 4) stored In the storage 47 other than the fourth part 60. Thus, because of a smaller surface tension of the top of the chemical liquid 200 stored in the fourth part 60, the gas downstream can move to downstream of the fourth part 60 through the fourth part 60. The present embodiment, can thus also attain effects similar to those of the second embodiment.

### Fourth Embodiment

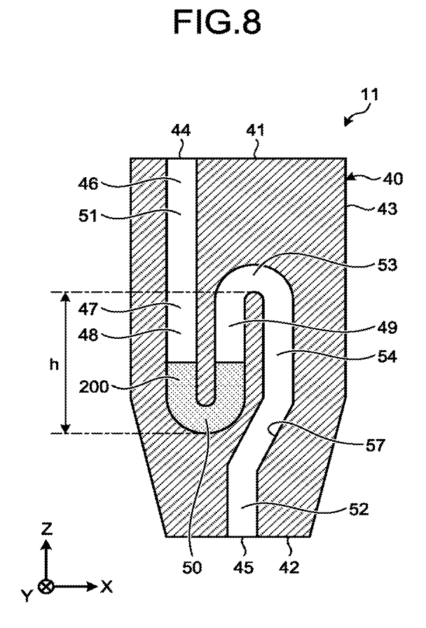

As illustrated in FIG. 8, the nozzle 11 of the present embodiment includes no exhaust 55. However, in the nozzle 11 of the present embodiment, as in the first embodiment, the arithmetic average roughness of a surface 57 of a flow channel 46 is set to larger than 10 μm. Because of this, the nozzle 11 in the present embodiment, as in the first embodiment, is prevented from dripping since the chemical liquid 200 remaining on the surface 57 is difficult to move.

### Fifth Embodiment

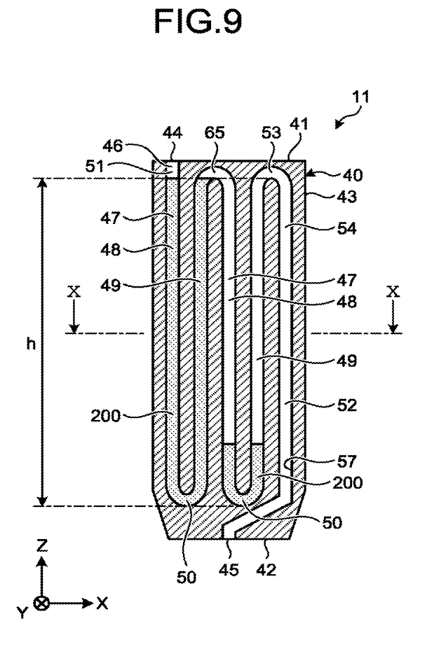

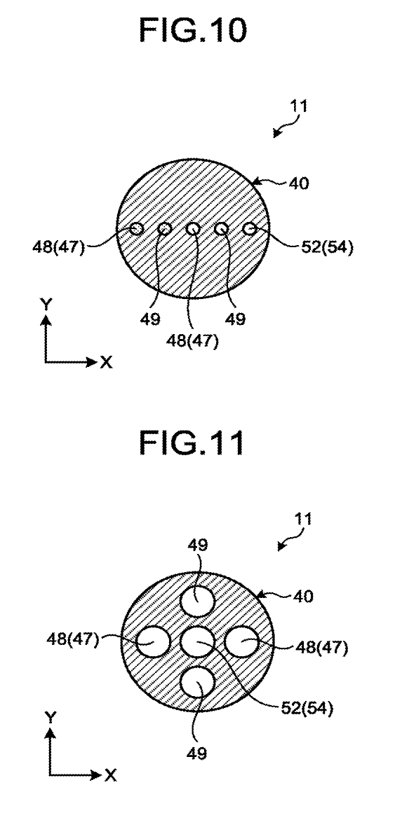

As illustrated in FIGS. 9 and 10, the nozzle 11 of the present, embodiment includes multiple (two, as an example) storages 47 in a flow channel 46. The nozzle 11 of the present embodiment, as in the fourth embodiment, includes no exhaust 55.

The storages 47 are aligned in a direction intersecting (orthogonal to, as an example) the vertical direction of a body 40. In the present embodiment, multiple first, parts 48 and multiple second parts 49 are aligned in one direction intersecting (orthogonal to, as an example) the vertical direction of the body 40. The storages 47 are connected through a connection 65. Specifically, a downstream end of the second part 49 of an upstream one of the two adjacent storages 47 is connected to an upstream end of the first part 48 of a downstream one thereof through the connection 65. The connection 65 has a downward bent shape (curved shape). Furthermore, in the present embodiment, the first part 48 of the most upstream one of the storages 47 is connected to a supply port 44 via a flow channel 51 while the second part 49 of the most downstream one of the storages 47 is connected to a vent 45 via a flow channel 52.

With the nozzle 11 having the above configuration, for example, the chemical liquid 200 is stored in the storages 47 in order from the most upstream one. FIG. 9 illustrates that the most upstream storage 47 is filled with the chemical liquid 200 and an overflowing chemical liquid 200 is stored in the downstream storage 47.

As described above, in the present embodiment, the body 40 includes the storages 47. Thus, the multiple storages 47 can store a larger amount of the chemical liquid 200 than one storage 47.

Furthermore, in the present embodiment, the storages 47 are aligned in the direction intersecting the vertical direction of the body 40. This makes it easier to elongate the vertical length of each storage 47 than when aligned in the vertical direction of the body 40.

### Sixth Embodiment

As illustrated in FIG. 11, the nozzle 11 of the present embodiment includes multiple storages 47. However, the present embodiment is different from the fifth embodiment in that multiple first parts 48 and multiple second parts 49 are disposed around a flow channel 52. This makes it easier to enlarge the diameter of the first parts 48 and the second parts 49, from when aligned in one direction intersecting the vertical direction of the body 40.

### Seventh Embodiment

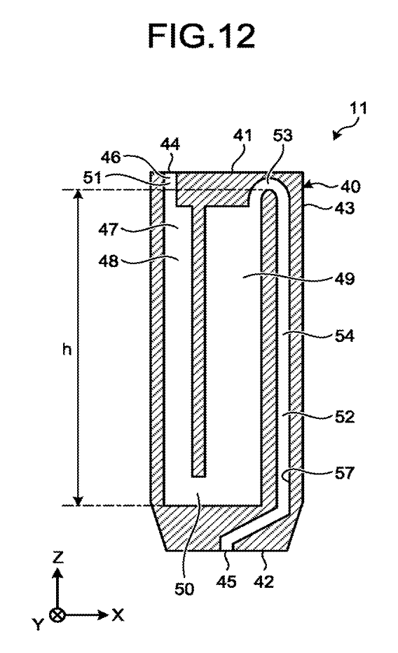

As illustrated in FIG. 12, in the nozzle 11 of the present embodiment, at least part (part, as an example) of a storage 47 has a larger cross section orthogonal to the extending direction of a flow channel 46 than a flow channel 52. Specifically, each of a part of a first part 48, a part of a second part 49, and a third part 50 has a larger cross section, orthogonal to the extending direction of the flow channel 46, than the flow channel 52. The flow channel 52 is an example of a part provided downstream of the storage 47, leading to a vent 45. Furthermore, the nozzle 11 of the present embodiment, as in the fourth embodiment, includes no exhaust 55.

As described above, according to the present embodiment, at least part (part, as an example) of the storage 47 of the present embodiment has a larger cross section, orthogonal to the extending direction of the flow channel 46, than the flow channel 52. Because of this, the storage 47 can store a larger amount of the chemical liquid 200 than the storage 47 having the same-size cross section, orthogonal to the extending direction of the flow channel 46, as the flow channel 52. The entire storage 47 may have a larger cross section orthogonal to the extending direction of the flow channel 46 than the flow channel 52.

### Eighth Embodiment

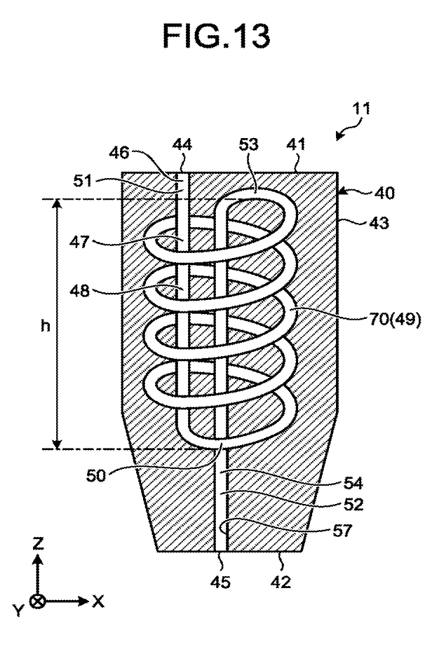

As illustrated in FIG. 13, the nozzle 11 of the present, embodiment includes a storage 47 that includes a spiral 70. At least one of a first part 48 and a second part 49 includes the spiral 70. Specifically, in the present embodiment, the spiral 70 is provided in the second part 49. The spiral 70 is a vertically extending spiral. The first part 48 and a flow channel 52 are disposed inside the spiral 70. The nozzle 11 of the present embodiment, as in the fourth embodiment, includes no exhaust 55.

As described above, in the present embodiment, the second part 49 of the storage 47 includes the spiral 70. Because of this, the storage 47 can store a larger amount of chemical liquid 200 than the one including a linear second part 49.

### Ninth Embodiment

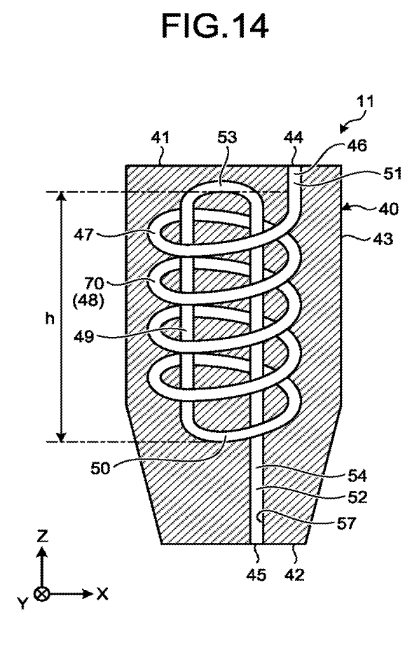

As illustrated in FIG. 14, the nozzle 11 of the present embodiment includes a spiral 70. However, the present embodiment is different from the eighth embodiment in that the spiral 70 is provided in a first part 48 of a storage 47. A second part 49 and a flow channel 52 are disposed inside the spiral 70. Furthermore, the nozzle 11 of the present embodiment, as in the fourth embodiment, includes no exhaust 55.

As described above, in the present embodiment, the first part 48 of the storage 47 includes the spiral 70. Because of this, the storage 47 can store a larger amount of chemical liquid 200 than the one including a linear first part 48.

### Tenth Embodiment

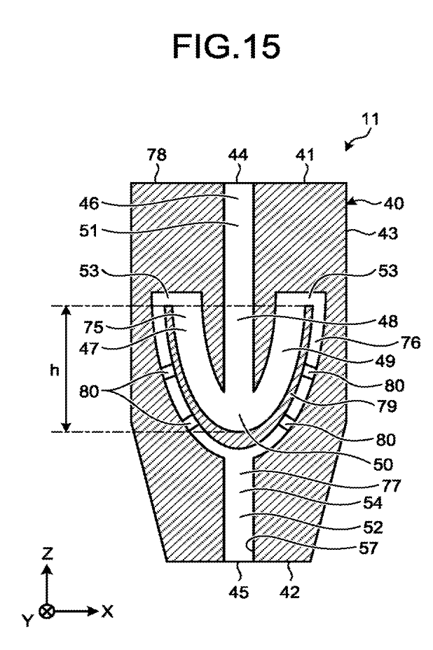

As illustrated in FIG. 15, the nozzle 11 of the present embodiment includes a second part 49 that includes a cylindrical part 75. The nozzle 11 of the present embodiment, as in the fourth embodiment, includes no exhaust 55.

The cylindrical part 75 has a cylindrical shape with a cylinder axis (center line) extending in the vertical direction of a body 40. The cylindrical part 75 decreases in diameter downward. A bottom end of the cylindrical part 75 is connected to a first part 48 via a third part 50 while a top end of the cylindrical part 75 is connected to an extension 54 via a connection 53 of a flow channel 52.

The extension 54 of the present embodiment Includes a cylindrical part 76. The cylindrical part 76 is disposed outside the cylindrical part 75 to surround the cylindrical part 75. The cylindrical part 76 has a cylindrical shape with a cylinder axis (center line) extending in the vertical direction of the body 40. The cylindrical part 76 decreases in diameter downward. A bottom end of the cylindrical part 76 is connected to a vent 45 via a linear part 77 while a top end of the cylindrical part 75 is connected to the extension 54 via the connection 53. The linear part 77 extends in the vertical direction of the body 40. The linear part 77 is included in the flow channel 52.

The body 40 includes a base 78, a wall 79, and a connection 80. The wall 79 is provided with a space inside the base 78, and connected to the base 78 through the connection 80. The wall 79 has a bottomed cylindrical shape. The connection 80 is provided partially around the cylinder axis of the wail 79 inside the cylindrical part 76. The two cylindrical parts 75 and 76 are formed between the base 78 and the wall 79.

As described above, in the present embodiment, the second part 49 includes the cylindrical part 75. This can, for example, improve the weight balance of the body 40 with the cylinder axis of the cylindrical part 75 coinciding with the axis of the body 40.

### Eleventh Embodiment

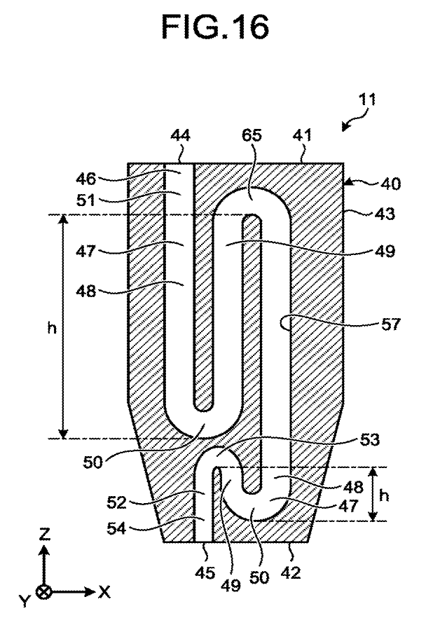

As illustrated in FIG. 16, the nozzle 11 of the present embodiment includes multiple storages 47 aligned in the vertical direction of a body 40. Specifically, second parts 49 of the two adjacent storages 47, an upstream one and a downstream one, are aligned with each other with a space in the vertical direction of the body 40.

As described above, in the present embodiment, the storages 47 are vertically arranged in the body 40. Because of this, the first parts 48 and the second parts 49 can be enlarged in diameter from when the storages 47 are arranged in the direction intersecting the vertical direction of the body 40.

In the above description, ordinals such as first and second are added to some constituent elements for convenience of explanation and they are replaceable when appropriate.

While several embodiments of the present invention nave been described, these embodiments have been presented as examples and are not intended to limit the scope of the invention. These novel embodiments can be implemented in various other forms, and various omissions, substitutions, and changes can be made without departing from the spirit of the invention. These embodiments and modifications thereof are included in the scope and gist of the invention, and are included in the invention described in claims and the equivalents thereof. For example, the nozzles 11 of the fifth to eleventh embodiments may include an exhaust 55. In addition to the chemical liquid for treating the surface of a workplace, chemical liquid may be water or paint for cleaning the surface after chemical treatment, for instance.

1. A nozzle comprising
a body provided with a supply port to which a liquid is supplied, a vent from which the liquid is discharged downward, and a flow channel that extends between the supply port and the vent,
wherein the flow channel includes:
a storage including a first part through which the liquid flows downward to the vent, and a second part provided downstream of the first part, through which the liquid flows upward to the vent; and
an exhaust capable of exhausting a gas upstream of the second part while the liquid is not discharged from the vent and is stored in the storage, wherein
the storage includes a third part connecting the first part and the second part, and
the exhaust includes a bypass channel that leads to parts upstream and downstream of the third part in the flow channel.

2. A nozzle comprising:
a body provided with a supply port to which a liquid is supplied, a vent from which the liquid is discharged downward, and a flow channel that extends between the supply port and the vent,
wherein an arithmetic average roughness of a surface of the flow channel is larger than 10 μm.

3. The nozzle according to claim 2,
wherein the flow channel includes:
a storage including a first part through which the liquid flows downward to the vent, and a second part provided downstream of the first part, through which the liquid flows upward to the vent.

4. The nozzle according to claim 3,
wherein the flow channel includes:
an exhaust capable of exhausting a gas upstream of the second part while the liquid is not discharged from the vent and is stored in the storage.

5. The nozzle according to claim 1,
wherein the storage includes a third part connecting the first part and the second part, and
the exhaust includes a bypass channel that leads to parts upstream and downstream of the third part in the flow channel.

6. A nozzle comprising:
The nozzle according to claim 1, wherein the bypass channel is connected to upstream of the first part and a point above the second part in the flow channel.

7. The nozzle according to claim 1, further comprising a plurality of the storages
wherein the exhaust includes a fourth part included in the second part, and
the fourth part has a larger cross section orthogonal to an extending direction of the flow channel than a rest of the storage.

8. The nozzle according to claim 1,
wherein the storage includes a plurality of the storages.

9. The nozzle according to claim 8,
wherein the storages are aligned in a direction intersecting an vertical direction of the
body.

10. The nozzle according to claim 8,
wherein the storages are aligned in the vertical direction of the body.

11. The nozzle according to claim 1,
wherein the flow channel includes a part provided downstream of the storage and leading to the vent, and
at least part of the storage has a larger cross section orthogonal to the extending direction of the flow channel than the part leading to the vent.

12. The nozzle according to claim 1,
wherein the flow channel includes a part provided downstream of the storage and leading to the vent, and
at least part of the storage has a larger cross section orthogonal to the extending direction of the flow channel than the part leading to the vent.

13. The nozzle according to claim 1,
wherein at least one of the first part and the second part includes a spiral.

14. The nozzle according to claim 1, wherein the second part includes a cylindrical part that extends in the vertical direction of the body.

15. A liquid supply device comprising:
a nozzle according to claim 1;
a supplier that supplies the liquid to the supply port.
